(19) United States
(12) Patent Application Publication
(10) Pub. No.: US 2011/0177651 A1
(43) Pub. Date: Jul. 21, 2011

(54) METHOD FOR PRODUCING A METAL STRUCTURE ON A SURFACE OF A SEMICONDUCTOR SUBSTRATE

(75) Inventors: Nicola Mingirulli, Berlin (DE); Daniel Biro, Freiburg (DE); Christian Schmiga, Freiburg (DE); Jan Specht, Freiburg (DE); David Stuwe, Freiburg (DE)

(73) Assignee: Fraunhofer-Gesellschaft Zur Forderung Der Angewandten Forschung E.V., Munchen (DE)

(21) Appl. No.: 12/997,427

(22) PCT Filed: Jun. 19, 2009
(86) PCT No.: PCT/EP2009/004424

§ 371 Date: Mar. 2, 2011

(30) Foreign Application Priority Data
Jun. 20, 2008 (DE) 10 2008 029 107.2

(51) Int. Cl. H01L 31/18

(52) U.S. Cl. 438/98; 257/E31.12

(57) ABSTRACT

A method for producing a metal structure on a surface of a semiconductor substrate, including the following steps: A applying a metal layer, B applying a structuring layer and C removing the structuring layer. Either step B is carried out after step A, and step C after step B in a masking method, so that the structuring layer covers the metal layer at least partially and, after step B is carried out, the metal layer is removed from the regions not covered by the structuring layer, before step C is carried out or, in a lift-off method, step A is carried out after step B, and step C after step A, so that the structuring layer is covered essentially by the metal layer and, at least in the regions, in which the metal layer covers the structuring layer, the metal layer is detached when step C is carried out. It is essential that the structuring layer in step B is produced by a hot melt ink.

### BACKGROUND

The invention relates to a method for the production of a metal structure on a surface of a semiconductor substrate.

For the production of a metal structure on a surface of a semiconductor substrate, methods are known in which, in a step A, a metal layer is deposited, in a step B, a structuring layer is deposited and, in a step C, the structuring layer is removed.

According to the sequence of steps A to C, one distinguishes between masking methods and lift-off methods:

For a masking method, initially the metal layer is deposited and the structuring layer is then deposited only in the areas in which the metal layer is to remain on the semiconductor substrate. At the places at which there is no structuring layer, the metal layer is removed, for example, by use of an etching substance that etches the metal layer but not the structuring layer.

Then the structuring layer is removed, so that, in the desired areas, only the metal layer remains and in this way the metal structure has been generated.

In a lift-off method, initially the structuring layer is deposited in the areas of the surface of the semiconductor substrate in which no metal structure is desired and then the metal layer is deposited essentially over the entire surface. Now, if, in step C, the structuring layer is then stripped off, then the metal layer is stripped off together with the structuring layer, but only in the areas in which structuring layer was found on the surface of the semiconductor substrate, so that, in the other areas, the metal layer remains on the surface and in this way the metal structure has been generated.

For the deposition of the structuring layer, different methods are known:

From chip fabrication, photolithographic methods are known in which structuring layers can be generated with high precision and with fine structures by the deposition of a photosensitive lacquer, exposure using an exposure mask, and development and selective removal of the exposed or the non-exposed lacquer. A disadvantage in photolithography is that the method is complicated and thus expensive and cannot be performed in an in-line process.

It is likewise known to generate structuring layers by a screen-printing method in which, through the use of a screen that provides the structure, printing paste is deposited using a printing squeegee through the screen onto the semiconductor substrate. This method is significantly less expensive, but has the disadvantage that fine structures cannot be produced by the screen-printing technique. Furthermore, with conventional methods, a combination of a lift-off and screen-printing method is not possible for the production of a metal structure.

In particular, for the production of solar cells it is important that, on one hand, fine metal structures are deposited for forming contacts for the solar cell and, on the other hand, the method is economical.

### SUMMARY

Therefore, the objective forming the basis of the invention is to provide a method for the production of a metal structure on a surface of a semiconductor substrate, wherein the method should allow an economical production of the metal structure with the simultaneous ability to generate fine structures. Furthermore, the method should be distinguished by not being susceptible to errors.

This objective is met by a method according to the invention.

The method according to the invention for the production of a metal structure on a surface of a semiconductor substrate thus comprises the following steps:

In a step A, a metal layer is deposited; in a step B, a structuring layer is deposited; and, in a step C, the structuring layer is removed.

Here, either in a masking method, step B is performed after step A, and step C is performed after step B, so that the structuring layer covers the metal layer at least partially and after execution of step B, the metal layer on the areas not covered by the structuring layer is removed before step C is performed.

Or, in a lift-off method, step A is performed after step B, and step C is performed after step A, so that the structuring layer is essentially covered by the metal layer and the metal layer is stripped off, in the execution of step C, at least in the areas in which the metal layer covers the structuring layer.

Here it lies in the scope of the invention that the mentioned steps follow one directly after the other. Likewise, however, it is also possible in the scope of the invention to insert additional intermediate steps between the mentioned steps A to C.

It is essential that the structuring layer in step B is generated by a hot-melt ink.

In contrast to the known methods, the structuring layer is thus generated neither by a photolithographic method nor by a screen-printing method, but instead by a hot-melt ink. Such inks are already known; they distinguish themselves in that they are solid at room temperature, but fluid at a processing temperature. The hot-melt ink is thus processed at an elevated temperature relative to room temperature and cools down after deposition on the semiconductor substrate, so that it becomes solid.

The deposition of the hot-melt ink is technically less complicated and thus less expensive relative to a photolithographic method.

Advantageously, the structuring layer has recesses that define the areas on which the metal structure is to be produced on the surface of the semiconductor substrate. Likewise, it lies in the scope of the invention that the structuring layer is made from several structuring individual layers lying one next to the other or that a combination of structuring individual layers and recesses is produced.

Advantageously, in step B, the hot-melt ink is deposited by a printing nozzle. In this way, in comparison with a screen-printing method, finer structures can be generated. In particular, it is advantageous that the printing nozzle is moved approximately parallel to the surface of the semiconductor substrate for the deposition of the hot-melt ink. Likewise, the kinematic inversion lies in the scope of the invention, i.e., such that the semiconductor substrate is moved approximately parallel to the printing nozzle or a combination of the movement of the printing nozzle and semiconductor substrate.

This deposition method of the hot-melt ink using a printing nozzle has the advantage that fine structures can be produced through the selection of a correspondingly fine printing nozzle. Furthermore, studies of the applicant have shown that, in particular, the surface of semiconductor substrates can have unevenness in the production of solar cells, so that for the use of a screen-printing method, the screen does not, in some parts, lie completely on the surface of the semiconductor substrate and therefore a larger number of defective structures is generated. Through the deposition of the hot-melt ink using a printing nozzle, possible unevenness of the surface of the semiconductor substrate is compensated, without distorting the specified structure.

Advantageously, the deposition of the hot-melt ink is realized with a non-contact method. In particular, it is advantageous that the hot-melt ink is deposited as described above by a printing nozzle and the printing nozzle is located at a distance of at least 100 μm from the surface of the semiconductor substrate.

In another advantageous configuration, the hot-melt ink is deposited in step B by a known inkjet printing method. The inkjet printing method is widely used especially in inkjet printers. An overview of the technology of the inkjet printing method is found in J. Heinzl, C. H. Hertz, “Inkjet Printing,” Advances in Electronics and Electron Physics, Vol. 65 (1985), pp. 91-112.

Thus, for the method according to the invention, the already known technology of the inkjet printing method could be used in order to generate a metal structure on a surface of a semiconductor substrate.

Studies of the applicant have shown, furthermore, that for the production of metal structures for contacting solar cells, the method according to the invention in the variant of the lift-off method is advantageous. Here, initially the structuring layer is thus deposited and then the metal layer. Advantageously, the metal layer is deposited such that the heat transfer from the metal layer to the structuring layer is small during the process of depositing the metal layer, in order to avoid renewed liquefaction, in particular, total liquefaction of the hot-melt ink.

Advantageously, the metal layer is deposited in step A by vacuum deposition, with a vacuum-deposition rate less than 10 Å/s (10×10⁻¹⁰ m/s) (angstrom per second), in particular, less than 5 Å/s (5×10⁻¹⁰ m/s), furthermore, less than 2 Å/s (10×10⁻¹⁰ m/s).

The tests of the applicant have shown that the heat transfer into the structuring layer becomes smaller the smaller the vacuum-deposition rate is during the deposition of the metal layer. Thus, through the mentioned, advantageous, maximum vacuum-deposition rates, renewed liquefaction of the hot-melt ink of the structuring layer is avoided, so that an exact structure definition is guaranteed by the structuring layer.

Furthermore, tests of the applicant have shown that the heat transfer into the structuring layer during the deposition of the metal layer depends on the thickness of the deposited metal layer. Therefore, for the configuration of the method according to the invention as the lift-off method, a metal layer is advantageously deposited whose thickness is not greater than 2000 nm.

For the production of metal structures with a total thickness greater than 2000 nm, a refinement of the method according to the invention is advantageous in which the metal layer is deposited step by step in partial layers with a partial layer thickness less than or equal to 2000 nm and after deposition of each partial layer, a cooling phase is carried out, so that the deposited partial layer and thus also the structuring layer cool down. In this way it is avoided that the structuring layer is heated to a temperature above the melting point. The duration of the cooling phase advantageously equals at least 10 minutes, advantageously at least 30 minutes.

In particular, for the contacting of solar cells, typically metal structures are used in which several materials are combined. Advantageously, the metal layer is therefore generated by the vacuum deposition of several conductive layers.

A known layer sequence for the production of a metal structure for the contacting of a solar cell is the layer sequence of titanium/palladium/silver.

Studies of the applicant have shown that, for avoiding subsequent liquefaction of the hot-melt ink, advantageously titanium is deposited with a vacuum-deposition rate less than 4 Å/s (4×10⁻¹⁰ m/s), palladium with a vacuum-deposition rate less than 5 Å/s (5×10⁻¹⁰ m/s), and silver with a vacuum-deposition rate less than 9 Å/s (9×10⁻¹⁰ m/s), in particular, titanium is deposited with a vacuum-deposition rate less than 2 Å/s (2×10⁻¹⁰ m/s), palladium with a vacuum-deposition rate less than 2 Å/s (2×10⁻¹⁰ m/s), and silver with a vacuum-deposition rate less than 3 Å/s (3×10⁻¹⁰ m/s).

Likewise, the use of a different number of layers and/or the use of different materials for generating the metal structure lies in the scope of the invention. The studies of the applicant have shown, furthermore, that, in particular, the use of a layer structure of aluminum/titanium/silver is advantageous for the method according to the invention.

Advantageously, all three layers are deposited with a vacuum-deposition rate less than 10 Å/s (10×10⁻¹⁰ m/s), in particular, less than 5 Å/s (5×10⁻¹⁰ m/s), furthermore, less than 2 Å/s (2×10⁻¹⁰ m/s).

Advantageously, the thickness of the aluminum layer lies in the range 300 nm to 1000 nm. The thicknesses of the titanium layer and/or silver layer lie advantageously in the range of 30 nm to 100 nm.

In particular, it is advantageous if the aluminum layer has approximately a thickness of 200 nanometers, the titanium layer approximately a thickness of 50 nanometers, and the silver layer likewise a thickness of approximately 50 nanometers.

Advantageously, for the method according to the invention, a hot-melt ink is used whose melting point lies in the range from 60° C. to 100° C., in particular, in the range from 70° C. to 80° C.

In another advantageous configuration of the method according to the invention, in step A the metal layer is deposited such that it essentially completely covers the surface of the semiconductor substrate or the structuring layer.

In the scope of this application, the phrase “surface of the semiconductor substrate” designates the surface on which the desired metal structure is deposited. This can be directly the surface of the semiconductor; likewise, however, the semiconductor substrate could also be made from a layer structure, wherein, on the uppermost layer of this structure (for example, an electrically insulating layer), the metal structure is to be deposited. In this case, “surface of the semiconductor substrate” thus designates the surface of the uppermost layer of the semiconductor structure.

The method according to the invention is therefore suitable, in particular, for generating a metal structure for contacting a semiconductor solar cell. Advantageously, the metal structure is therefore a contacting structure for a semiconductor solar cell, wherein the solar cell is constructed by the semiconductor substrate.

In particular, for solar cells contacted on one side, the method according to the invention is advantageous:

For solar cells contacted on one side, the metallization structures for contacting both electrical contacts are located on one surface of the solar cell and not, as usually typical, on opposite faces.

The method according to the invention is therefore suitable, in particular, for the production of solar cells contacted on one side, in which, on one surface of the semiconductor substrate, at least two metal structures are constructed, wherein one metal structure is the p-contacting structure and the other metal structure is the n-contacting structure of the solar cell and both contacting structures are produced by the method according to the invention.

In particular, it is advantageous when both contacting structures are produced from the metal layer deposited in step A, such that, by use of the method according to the invention, a contact separation takes place, so that a portion of the metal layer deposited in step A is the p-contacting structure and a different portion of the metal layer is the n-contacting structure.

Here it is desirable to achieve, on one hand, the most interdigitated configuration possible for the two contacting structures, in order to allow short paths for the charge carriers from the semiconductor substrate into the corresponding contact structure and thus to minimize loss mechanisms, such as, series-resistance losses and recombination losses. Likewise, however, it is important to guarantee an exact separation between the two metallic contacting structures, in order to exclude losses due to short circuits.

For generating such metal structures for solar cells contacted on one side, the use of the method according to the invention is advantageous, because in this way fine metal structures can be generated and simultaneously the method according to the invention represents an economical method, in particular, with respect to photolithographic methods.

In particular, the method according to the invention is used advantageously for the production of EWT solar cells. This known solar cell structure is described, for example, in U.S. Pat. No. 5,468,652. For an EWT solar cell, the semiconductor substrate has holes standing approximately perpendicular to the surface of the semiconductor substrate and through which the emitter of the solar cell is guided from the front side to the rear side of the solar cell, wherein both the contacting of the emitter and also the base of the solar cell are realized on the back side of the solar cell and thus both metallic contacting structures are also arranged on the back side of the EWT solar cell.

Studies of the applicant have shown that, in particular, for the manufacturing process of an EWT solar cell, the production of the holes for the use of a multi-crystalline, semiconductor substrate can lead to unevenness on the surface of the semiconductor substrate and therefore, in particular, for this solar-cell structure, the method according to the invention distinguishes itself for the production of the metallic contacting structure.

Advantageously, the method according to the invention therefore also comprises the following steps:

i. production of several recesses in the semiconductor substrate, wherein the recesses penetrate the semiconductor substrate approximately perpendicular to the surface of the semiconductor substrate,

ii. stripping of a thin layer from the surface of the semiconductor substrate, as well as the recesses, for avoiding contaminants and crystal defects,

iii. production of at least two oppositely doped regions in the semiconductor substrate for the production of a pn junction, and

iv. deposition of a metal structure as contacting structure, wherein the contacting structure is connected in an electrically conductive way to at least one doped region.

Advantageously, between step iii and iv, an electrically insulating layer, such as, for example, a dielectric layer, is deposited, so that the metal structure is deposited essentially on the insulating layer and an electrical contact to the semiconductor substrate is generated only in provided areas. This electrical contact can be generated, for example, such that the insulating layer has recesses through which the metal structure is in electrically conductive connection to the semiconductor substrate.

Furthermore, it is advantageous if, in step iv, after deposition of the metal structure, this is reinforced for improving the conductivity. In particular, it is advantageous to reinforce the metal structure by a known galvanic method, i.e., to reinforce with a current-induced method.

For the hot-melt ink being used, the following properties are essential:

For one, the ink must have a melting point that lies above room temperature. Furthermore, the hot-melt ink must be removable by a solvent. If the method is constructed as a masking method, the hot-melt ink must also be resistant to the substance being used for etching the metal.

Such suitable hot-melt inks are already known. The use of hydrocarbon wax hot-melt ink has been shown to be advantageous.

In particular, the use of the hot-melt inks with the designation “Jet 3568,” “JetP 3568,” “U 5569,” and “U 5315” from Sunjet, Norton Hill, Midsommer Norton, Bath BA3 4RT, United Kingdom is advantageous.

As described above, in particular, for the configuration of the method according to the invention as a lift-off method, the risk arises that for the deposition of the metal layer, liquefaction of the hot-melt ink takes place and therefore a defective structure is generated.

In one advantageous configuration of the method according to the invention, a UV-cured hot-melt ink is used. This has the property that it is cured by the effect of UV radiation, so that liquefaction no longer takes place even for a subsequent temperature application.

Advantageously, therefore, for the method according to the invention, the structuring layer is produced in step B by a UV-curing hot-melt ink. In particular, it is advantageous, after step B, i.e., after deposition of the structuring layer, to irradiate this layer with UV radiation, so that the desired curing of the structuring layer is performed.

Typical UV-curing hot-melt inks are cured by radiation in the wavelength range from 200 nm to 450 nm, wherein advantageously a quantity of energy from 100 mJ to 500 mJ is introduced into the hot-melt ink for curing. As the radiation source, the use of a mercury vapor lamp is advantageous.

In particular, the configuration of the method according to the invention as a lift-off method in combination with the configuration of the hot-melt ink as a UV-curing hot-melt ink is advantageous.

For the method according to the invention, advantageously hot-melt inks are used that can be removed in step C by solvent that does not etch the semiconductor substrate, in particular, does not etch silicon. In this way, the advantage is achieved that, in step C, when the structuring layer is removed, a negative effect on the semiconductor substrate is not realized. In particular, it is advantageous to use hot-melt inks that can be removed by aromatic solvents and, accordingly, to remove, in step C, the structuring layer by one or more aromatic solvents.

In another advantageous configuration of the method according to the invention, after deposition of the structuring layer in step B, a reheating process is performed, i.e., a subsequent heating of the structuring layer. In this way, the adhesion of the structuring layer to the surface of the semiconductor substrate is increased, so that, in the subsequent processing steps, the risk of stripping off the structuring layer at the edges or an undercut of the structuring layer at the edges for subsequently performed chemical treatments, in particular, under-etching at the edge regions, is reduced. Advantageously, the reheating is performed for a time period in the range of 1 minute to 2 minutes at a temperature in the range between 40° C. and 60° C., in particular, for a time period of approximately 90 seconds at a temperature between 50° C. and 60° C. It is essential that the melting point of the hot-melt ink is not reached during the reheating.

Typically, the processing of the hot-melt inks is performed during the deposition of the structuring layer in step B at a temperature of the hot-melt inks lying approximately 10° C. above the melting point of the hot-melt inks. This is based on the fact that the viscosity of the hot-melt inks decreases with increasing temperature and therefore better processing is possible in that the hot-melt ink is not processed at a temperature directly above the melting point, but instead at a somewhat higher temperature.

Studies of the applicant have shown that the temperature difference between the hot-melt ink and the semiconductor substrate in step B has a significant effect on the flanks of the edges of the structuring layer deposited in step B: for a higher temperature difference, steeper flanks are produced, i.e., starting from the surface of the semiconductor substrate, a steeper slope is produced at the edges of the structuring layer. Now it is advantageous that the structuring layer has a flank that is as steep as possible. In particular, flanks that are nearly perpendicular to the surface of the semiconductor substrate are advantageous or structuring layers that have, at the edges, an overhang relative to the surface of the semiconductor substrate, i.e., a slope angle greater than 90° between the surface of the semiconductor substrate and structuring layer at the edge.

Typically, as constructed before, the processing of the hot-melt ink is performed at a temperature lying approximately 10° C. above the melting point and the semiconductor substrate is typically at room temperature, i.e., 25° C. For achieving the mentioned advantages, in one advantageous embodiment of the method according to the invention, the temperature difference in step B increases for the deposition of the structuring layer between the hot-melt ink and semiconductor substrate by at least 10° C., advantageously at least 20° C., further advantageously at least 40° C., in particular, by 60° C. This can be achieved in that the hot-melt ink is processed at a correspondingly elevated temperature and/or the semiconductor substrate in step B is cooled down for the deposition of the structuring layer.

In order to avoid too high a temperature of the hot-melt ink in the processing in step B, it is advantageous to cool the semiconductor substrate in step B, in particular, by approximately 10° C.

Alternatively or additionally, it is advantageous to increase the melting point of the hot-melt ink. This is achieved advantageously by changing the composition of the hot-melt ink, in particular, by the addition of an additional component to the hot-melt ink. Alternatively or additionally, the high-melting-point components of the hot-melt ink could be increased.

The increase in the melting point has the advantage that, on one hand, in step B during the deposition of the structuring layer, the temperature difference between the hot-melt ink and semiconductor substrate is increased, but, on the other hand, the viscosity could be selected independent of this fact, by performing, for example, as described above, the processing of the hot-melt ink approximately 10° C. above the melting point.

The mentioned increase in the temperature difference is advantageous, in particular, in the variant of the method according to the invention as a lift-off method, because here, by the steep configuration of the flanks, a coverage of the flanks by the metal layer is prevented, so that, in step C, an attack of the solvent on the flanks of the structuring layer is promoted and thus an acceleration of the method step C is achieved.

Furthermore, for the use of the lift-off method for a given thickness of the metal layer, a minimum structure width is necessary, in order to achieve a reliable production of the specified structure. The thicker the metal layer, the larger the minimum structure width. Due to the mentioned increase in the temperature difference and the steeper flanks achieved in this way, however, for the specified thickness of the metal layer, a structure with smaller width can be printed. The increase in the temperature difference thus allows, for a specified thickness of the metal layer, the production of finer structures, in particular, linear openings/recesses in the metal layer with smaller width.

### BRIEF DESCRIPTION OF THE DRAWINGS

Additional features and advantageous configurations of the method according to the invention are described below with reference to the figures. Shown herein are:

FIG. 1 an embodiment of the method according to the invention as a masking method and

FIG. 2 an embodiment of the method according to the invention as a lift-off method.

### DETAILED DESCRIPTION OF THE PREFERRED EMBODIMENTS

Both embodiments of the method according to the invention shown in the figures have in common that the metallic contacting structures of a semiconductor solar cell are produced by the method according to the invention.

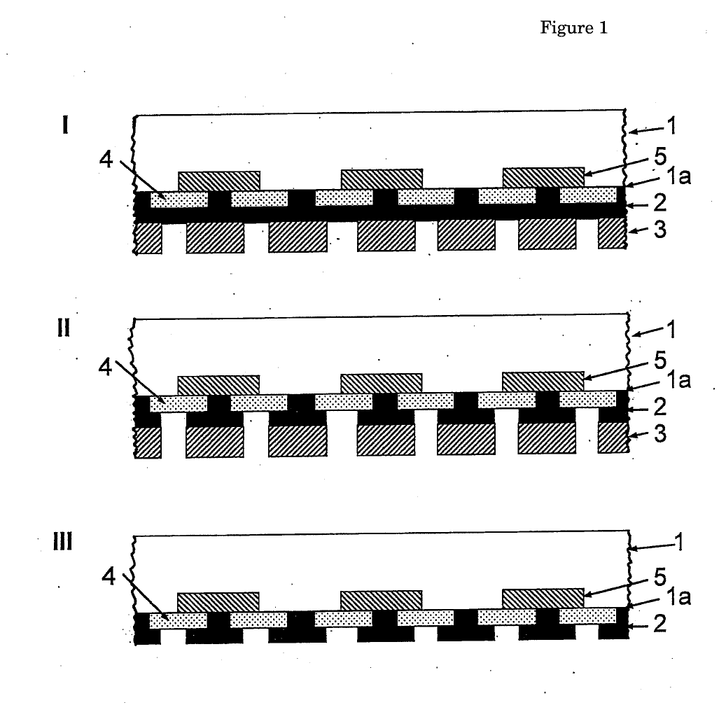

The solar cell is made from a p-doped semiconductor substrate 1 on whose back side 1a, strip-shaped n-doped regions 5 are located that are shown in cross section in FIG. 1, i.e., extend perpendicular to the plane of the drawing.

Furthermore, on the back side 1a of the substrate 1, an insulating structure 4 is deposited that covers the boundaries between the n-doped regions 5 and the p-doped substrate 1 on the back side 1a.

This insulating structure 4 can be made, for example, from a dielectric, such as, for example, silicon dioxide. The structuring of the insulating structure 4 can be performed, for example, by laser ablation or by a known masking method and corresponding chemical stripping.

For the embodiment shown in FIG. 1 for the method according to the invention, in a step I the full-surface-area coating of the back side 1a of the substrate 1 (or the insulating structure 4) is performed with a metal layer 2. The metal layer 2 here consists of 3 metal layers: one aluminum layer, one palladium layer, and one silver layer, wherein the layers are each deposited by vacuum deposition.

Furthermore, in step I, in FIG. 1 a structuring layer 3 has already been deposited. This structuring layer 3 is made from hot-melt ink that was deposited by an inkjet printing method. The structuring layer 3 is structured such that it covers the areas between the insulating layer 4, i.e., between the individual linear elements of the structuring layer 3, linear, free regions that extend perpendicular to the plane of the drawing in FIG. 1 are produced. These linear regions have a width (parallel to the surface 1a) between 30 μm and 300 μm.

The step I shown in FIG. 1 thus includes the steps A and B according to the above description.

In step II according to FIG. 1, the state after etching of the metal layer 2 is shown: the solar cell was treated with a substance that strips metal by an etching process. Because the hot-melt ink and the insulating layer 4 are resistant to this substance, the metal layer 2 was stripped, as shown in FIG. 1, II, only in the linear regions between structuring layer 3 and insulating layer 4.

Finally, in a step III, the structuring layer 3 is stripped using a solvent. Step III thus includes step C according to the above description.

As seen in FIG. 1, III, a metallic structure was generated by the method according to the invention, wherein this structure has linear configurations that are connected alternately to an n-region or the p-substrate of the solar cell. At the edges of the solar cell, (not shown) connection regions of these metal fingers were produced (so-called busbars), so that, on the back side of the solar cell 2, metallization structures engaging in each other like combs were produced.

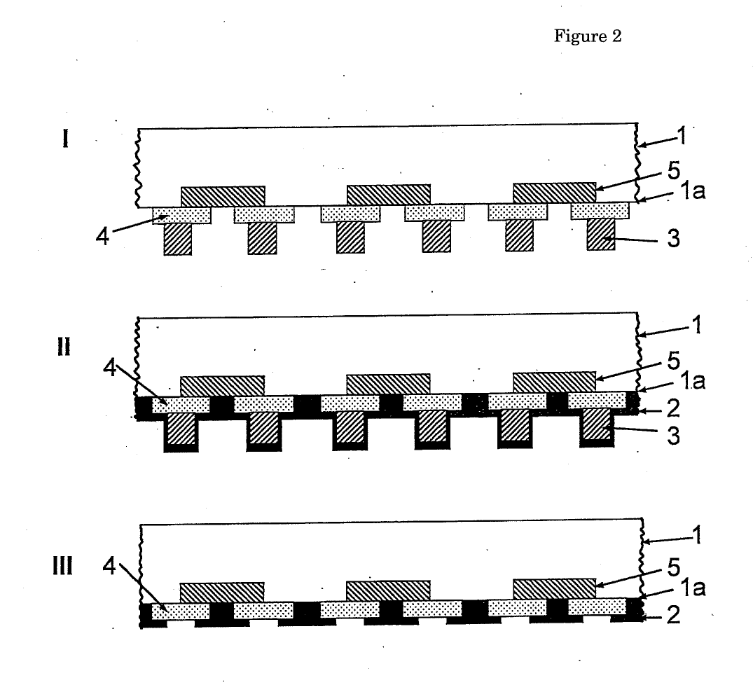

In FIG. 2, an embodiment of the method according to the invention is shown in which a metal structure is generated by a lift-off method.

Here, the same starting situation exists as in the description of FIG. 1, i.e., a p-doped semiconductor substrate 1 on whose back side 1a n-doped regions 5 are constructed, wherein, on the back side 1a, an insulating layer 4 was deposited that covers the boundaries between n-doped regions 5 and p-substrate in a linear shape.

Furthermore, a structuring layer 3 was deposited that was made from hot-melt ink and was produced using an inkjet printing method. The structuring layer 3 likewise has linear structures, wherein the linear structures of the structuring layer 3 are each arranged on the linear structures of the insulating layer 4 and have a smaller line width than the lines of the insulating layer 4, so that the structuring layer 3 lies merely on the insulating layer 4, but not directly on the n-doped regions 5.

Step I in FIG. 2 thus comprises step B according to the above description.

In step II according to FIG. 2, a full-surface-area metal layer 2 is deposited on the back side of the substrate 1, wherein the metal layer 2 covers both the open p-doped regions of the substrate 1, the open n-doped regions 5, as well as the insulating layer 4 and the structuring layer 2.

Step II according to FIG. 2 thus comprises step A according to the above description.

Thus, for the configuration of the method according to the invention as a lift-off method, the metal layer is deposited after the structuring layer. In this case, a heat transfer due to the deposition of the metal layer 2 on the structuring layer 3 could thus lead to renewed liquefaction of the hot-melt ink of the structuring layer 3, so that defective structures could be produced.

Therefore it is essential that for the deposition of the metal layer 2, the vacuum-deposition rates are selected such that liquefaction of the hot-melt ink is prevented. In the embodiment shown in FIG. 2, in step II the metal layer is likewise produced from 3 layers, wherein initially an aluminum layer is deposited with a vacuum-deposition rate of 1 Å/s (1×10⁻¹⁰ m/s), then a palladium layer with a vacuum-deposition rate of 1 Å/s (1×10⁻¹⁰ m/s), and finally a silver layer with a vacuum-deposition rate of 2 Å/s (2×10⁻¹⁰ m/s). Through these vacuum-deposition rates, it is guaranteed that total liquefaction of the hot-melt ink is not realized.

Finally, in a step III according to FIG. 2, the structuring layer 3 is removed using a solvent, so that the metal layer 2 is also removed in the regions in which the metal layer 2 covers the structuring layer 3. Step III in FIG. 2 thus comprises step C according to the above description.

The produced metal structure according to FIG. 2, III thus corresponds to the structure according to FIG. 1, III.

1. Method for producing a metal structure on a surface of a semiconductor substrate, comprising the following steps:
A depositing a metal layer (2),
B depositing a structuring layer (3), and
C removing the structuring layer (3),
wherein, either, in a masking method, step B is performed after step A, and step C is performed after step B, so that the structuring layer (3) at least partially covers the metal layer (2) and after execution of step B, the metal layer (2) in areas not covered by the structuring layer (3) is removed before step C is performed or, in a lift-off method, step A is performed after step B, and step C is performed after step A, so that the structuring layer (3) is essentially covered by the metal layer (2) and the metal layer (2) is stripped off, in the execution of step C, at least in the areas in which the metal layer (2) covers the structuring layer (3), and the structuring layer (3) is generated in step B by a hot-melt ink.

2. Method according to claim 1, wherein the structuring layer (3) has recesses or is made from several structuring individual layers arranged one next to the other.

3. Method according to claim 1, wherein in step B the hot-melt ink is deposited by a printing nozzle, and the printing nozzle for deposition of the hot-melt ink is moved approximately parallel to a surface of the semiconductor substrate.

4. Method according to claim 1, wherein the deposition of the hot-melt ink is performed with a non-contact method.

5. Method according to claim 1, wherein in step B, the hot-melt ink is deposited by an inkjet printing method.

6. Method according to claim 1, wherein in the lift-off method, step A is performed after step B and step C is performed after step A, and the metal layer (2) is deposited in step A by vacuum deposition with a vacuum-deposition rate less than 10 Å/s (10×10⁻¹⁰ m/s).

7. Method according to claim 6, wherein the metal layer (2) comprises several individual layers and is generated by vacuum deposition of titanium, palladium, and silver, wherein the titanium is deposited with a vacuum-deposition rate less than 4 Å/s (4×10⁻¹⁰ m/s), the palladium is deposited with a vacuum-deposition rate less than 5 Å/s (5×10⁻¹⁰ m/s), and the silver is deposited with a vacuum-deposition rate less than 9 Å/s (9×10⁻¹⁰ m/s).

8. Method according to claim 6, wherein the metal layer (2) comprises several individual layers and is generated by the vacuum deposition of aluminum, titanium, and silver, and all 3 layers are each deposited with a vacuum-deposition rate less than 2 Å/s (2×10⁻¹⁰ m/s).

9. Method according to claim 1, wherein the hot-melt ink used has a melting point that lies in the range from 60° C. to 100° C.

10. Method according to claim 1, wherein in step A the metal layer (2) is deposited such that it essentially completely covers the surface of the semiconductor substrate or the structuring layer (3).

11. Method according to claim 1, wherein the metal structure is a contacting structure for a semiconductor solar cell, and the solar cell is constructed by the semiconductor substrate.

12. Method according to claim 11, wherein on the surface of the semiconductor substrate, at least two metal structure are constructed, wherein one metal structure is a p-contacting structure and the other metal structure is an n-contacting structure of the solar cell and both of the contacting structures are produced by the method.

13. Method according to claim 12, wherein the metal layer is deposited in step A essentially over the entire surface and the structuring layer is constructed such that both the n-contacting structure and also the p-contacting structure are generated from the metal layer by contact separation.

14. Method according to claim 13, wherein in step A, before the deposition of the metal layer (2), a structured isolation layer (4) is also deposited on the surface of the semiconductor substrate, with the structured isolation area on the surface extending into areas in which the p-contacting and n-contacting structures border each other.

15. Method according to claim 14, wherein the solar cell has an EWT structure and the method also comprises the following steps
i producing several recesses in the semiconductor substrate, wherein the recesses penetrate the semiconductor substrate approximately perpendicular to the surface of the semiconductor substrate,
ii stripping a small layer from the surface of the semiconductor substrate, as well as the recesses, for avoiding contaminants and crystal defects,
iii producing at least two oppositely doped regions in the semiconductor substrate for the production of a p-n junction, and
iv depositing the metal structure as a contacting structure, wherein the contacting structure is connected electrically conductively to at least one doped region.

16. Method according to claim 15, wherein the solar cell has at least of the two metal structures engaging in each other like combs on the surface of the semiconductor substrate, and at least one of the metal structures is generated with the method, in particular, the solar cell is a solar cell that can be contacted on one side.

17. Method according to claim 1, wherein the hot-melt ink is a hydrocarbon wax.

18. Method according to claim 1, wherein after deposition of the metal structure, the metal structure is reinforced.

19. Method according to claim 1, wherein the structuring layer (3) is generated in step B by a UV-cured hot-melt ink.

20. Method according to claim 19, wherein after step B, the structuring layer is irradiated with UV radiation for curing the UV-cured hot-melt ink.

21. Method according to claim 1, wherein in step B, a temperature difference between the semiconductor substrate and the hot-melt ink is increased by at least one of cooling the semiconductor substrate or heating the hot-melt ink to a higher temperature.

22. Method according to claim 21, wherein the melting point of the hot-melt ink is increased.
